(19) United States
(12) Patent Application Publication
(10) Pub. No.: US 2002/0163369 A1
(43) Pub. Date: Nov. 7, 2002

(54) Operating method for two data buses

(76) Inventors: Martin Peller, Muenchen (DE); Josef Berwanger, Poing (DE)

Correspondence Address: CROWELL & MORING LLP, INTELLECTUAL PROPERTY GROUP, P.O. BOX 14300, WASHINGTON, DC, 20044-4300, US

(21) Appl. No.: 10/114,317

(22) Filed: Apr. 3, 2002

Related U.S. Application Data
(63) Continuation of application No. PCT/EP00/08787, filed on Sep. 8, 2000.

(30) Foreign Application Priority Data
Oct. 4, 1999 (DE) 199 47 660.8

(51) Int. Cl. H03L 7/00

(52) U.S. Cl. 327/144

(57) ABSTRACT

The invention relates to an operating method for two data buses, each with a clock generator. The clock generators are synchronized with one another, by the clock generator of the higher frequency synchronizing the clock generator of the lower frequency to its own clock pulse frequency.

### CROSS-REFERENCE TO RELATED APPLICATIONS

This application is a continuation of PCT Application No. PCT/EP00/08787 filed Sep. 8, 2000.

This application is related to copending applications entitled “Data Bus for Several Users”, U.S. Ser. No. ______; “Operating Method for a Data Bus for Several Users With Flexible Timed Access”, U.S. Ser. No. ______; and “Operating Method for a Data Bus”, U.S. Ser. No. ______, filed on even date herewith.

### BACKGROUND AND SUMMARY OF THE INVENTION

The invention relates to an operating method for two data buses, each having a clock pulse generator.

Data buses which can be used within the scope of the invention are disclosed in German Patent document DE 19720401 A. The data bus described therein as an example preferably has a star-type topology. However, it may also have a bus topology known per se in which the users communicate with one another by way of one or several data lines. The data bus contains a bus master which generates synchronization pulses, so that the communication can take place between the users.

If this clock pulse generator fails, it is, as a rule, no longer possible to communicate. In order to prevent this, a redundant system design can be selected by using two data buses with pertaining users (in the following called a bus cluster). In the event of a failure of a bus master, the other bus cluster will continue to run and the data exchange will continue to be possible between the various users of this bus cluster.

In the normal operation, that is, when both bus clusters are operable, they run in an unsynchronized manner unless additional measures are taken. The lack of synchronism causes a certain jitter between communications or data which are transmitted via one or the other bus cluster and are also used in the other bus cluster. If this jitter exceeds a certain value, it may be disadvantageous for the behavior of control systems in which the reaction time is within the range of the communication cycle time.

It is an object of the invention to provide an operating method for two data buses, which each have their own clock pulse generator, by means of which operating method the above-described jitter problem can be avoided.

This problem is solved by an operating method for two data buses which each have a clock pulse generator, characterized in that the clock pulse generators are mutually synchronized in that the clock pulse generator with the higher frequency synchronizes the clock pulse generator with the lower frequency to its clock pulse frequency.

Other objects, advantages and novel features of the present invention will become apparent from the following detailed description of the invention when considered in conjunction with the accompanying drawings.

### BRIEF DESCRIPTION OF THE DRAWINGS

FIG. 1 is a flow chart illustrating an operating method according to the present invention.

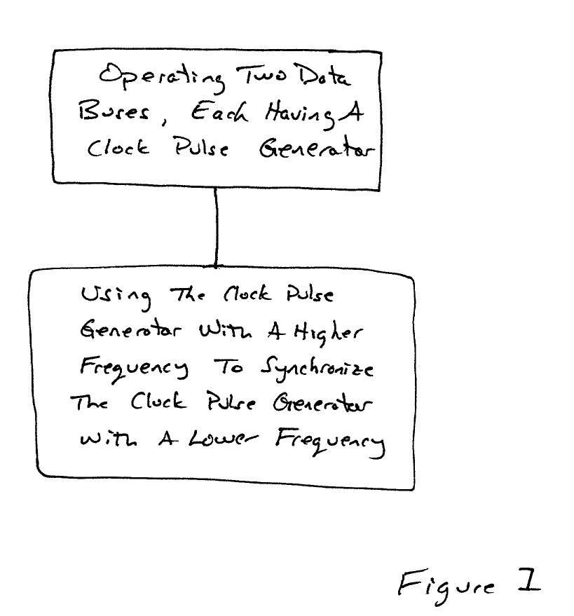

### DETAILED DESCRIPTION OF THE DRAWINGS

A prerequisite of the invention is the use of one or several synchronization lines between the clock pulse generators of the various bus clusters. These synchronization lines may be constructed, for example, as a wired AND connection in order to be able to synchronize more than two clock pulse generators. It is also possible to provide, in the case of each clock pulse generator, one input and output respectively for the synchronization mechanism. In this case, the outputs of each bus master can be led by way of dc decoupling to the inputs of all other clock pulse generators. This causes a wider availability of the synchronization mechanism. The various clock pulse generators synchronize one another such that the clock pulse generator with the “fastest clock”, that is, the clock pulse generator with the highest frequency, always prevails with its synchronization sequence and synchronizes the other clock pulse generator.

This clock pulse generator accepts a resynchronization only within a certain time window, which is defined by the permitted crystal tolerances. In contrast, the first resynchronization after the power-up or wake-up is always accepted. As a result, it is prevented that, by means of a bus master whose clock pulse generator clearly operates too rapidly, the communication cycle of the other bus cluster is unacceptably shortened.

If a resynchronization attempt of a bus master takes place which cannot be accepted because it is outside the permissible tolerance ranges, this is appropriately reported to the data bus system or to the users, so that corresponding measures can be taken at the system level. These measures may consist of entering a normal state or an emergency state, or of only carrying out measures which are not critical.

By means of this solution, mutually independent data bus clusters can be synchronized. This offers advantages for the behavior of control systems which exchange data over different bus clusters.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. An operating method, comprising the acts of:
operating two data buses, each data bus having a clock pulse generator;
mutually synchronizing each of the clock pulse generators, wherein a clock pulse generator having a higher frequency synchronizes a clock pulse generator having a lower frequency to its own clock pulse frequency.

2. The operating method according to claim 1, further comprising the act of stopping transmission operation of the clock pulse generator with the lower frequency.

3. The operating method according to claim 1, wherein the clock pulse generator with the lower frequency is synchronized to the clock pulse generator with the higher frequency only if the clock pulse frequency with the higher frequency does not exceed a defined rate.
